(19) United States
(12) Patent Application Publication
(10) Pub. No.: US 2026/0090284 A1
(43) Pub. Date: Mar. 26, 2026

(54) QUANTUM PROCESSING SYSTEMS WITH ENGINEERED RELAXATION TIMES

(71) Applicant: Silicon Quantum Computing Pty Limited, Kensington (AU)

(72) Inventors: Yu-Ling Hsueh, Kensington (AU); Daniel Keith, Kensington (AU); Rajib Rahman, Kensington (AU); Yousun Chung, Kensington (AU); Michelle Yvonne Simmons, Kensington (AU); Samuel Keith Gorman, Kensington (AU); Md Serajum Monir, Kensington (AU)

(21) Appl. No.: 19/163,352

(22) PCT Filed: Mar. 6, 2024
(86) PCT No.: PCT/AU2024/050177

§ 371 Date: Sep. 8, 2025

(30) Foreign Application Priority Data
Mar. 6, 2023 (AU) 2023900594

(51) Int. Cl. H10N 60/10; B82Y 10/00; H10N 60/01

(52) U.S. Cl. CPC H10N 60/11; H10N 60/01; H10N 60/128; B82Y 10/00

(57) ABSTRACT

Quantum processing systems and methods for fabrication are disclosed. The quantum processing system includes a semiconductor substrate; a dielectric material forming an interface with the semiconductor substrate; a dopant dot formed in the semiconductor substrate, the dopant dot comprising one or more dopant atoms; and one or more electrons/holes confined to the dopant dot. The system further includes a means for providing a magnetic field, wherein the magnetic field is applied in a particular direction to a crystallographic axis of the semiconductor substrate such that a relaxation time of the electron/hole is maximized.

### TECHNICAL FIELD

Aspects of the present disclosure are related to quantum processing systems and more particularly to quantum processing elements with engineered relaxation times.

### BACKGROUND

Large-scale quantum processing systems hold the promise of a technological revolution, with the prospect of solving problems which are out of reach with classical machines. To date, a number of different structures, materials, and architectures have been proposed to implement quantum processing systems and to fabricate their basic information units (quantum bits or qubits). Qubits can be understood as quantum-mechanical systems encoded into two discrete energy levels.

Semiconductor spin qubits have now reached high enough figures of merit to envision large scale error-corrected architectures for quantum information processing. However, before such large-scale quantum computers can be manufactured commercially, a number of hurdles need to be overcome. One such hurdle is qubit relaxation time.

Qubit relaxation time refers to the time it takes for a qubit to lose its quantum coherence. That is, it is the time taken for a qubit to “relax” or become disentangled from its environment. Relaxation time is often an important parameter in quantum computing, as it sets the upper limit on the time for which a qubit can maintain its quantum state. In practical terms, it determines how long information can be stored in a qubit before it is lost due to noise and other environmental factors.

There are different mechanisms that can cause qubit relaxation, such as interaction with the surrounding electromagnetic field, thermal fluctuations, and material defects. Further, relaxation times can vary widely depending on the qubit technology, ranging from microseconds to seconds or even longer in some cases.

Maximizing the relaxation time is a goal in the development of qubit technologies, as it would enable longer coherence times and more robust quantum operations.

### SUMMARY

According to a first aspect of the present disclosure there is provided a quantum processing system comprising: a semiconductor substrate: a dielectric material forming an interface with the semiconductor substrate: a dopant dot formed in the semiconductor substrate, the dopant dot comprising one or more dopant atoms; and one or more electrons/holes confined to the dopant dot. The system further includes a means for providing a magnetic field, wherein the magnetic field is applied in a particular direction to a crystallographic axis of the semiconductor substrate such that a relaxation time of the electron/hole is maximized.

According to a second aspect of the present disclosure, there is provided a quantum processing system comprising: a semiconductor substrate: a dielectric material forming an interface with the semiconductor substrate: a dopant dot formed in the semiconductor substrate comprising a plurality of dopant atoms and one or more electrons/holes confined within the dopant dot. The dopant atoms of the dopant dot are positioned in the semiconductor substrate to have a particular dopant dot axis such that a relaxation time of the electron/hole is maximized.

According to some aspects, the quantum processing system of the second aspect further includes a means for providing a magnetic field that is applied in a particular direction with respect to the dopant dot axis such that the relaxation time of the electron/hole is maximized.

According to a third aspect of the present disclosure, there is provided a quantum processing system comprising: a semiconductor substrate: a dielectric material forming an interface with the semiconductor substrate: a dopant dot comprising a plurality of dopant atoms and one or more electrons/holes confined within the dopant dot. The dopant atoms of the dopant dot are positioned in the semiconductor substrate to have a particular inter donor atom axis. The system further comprises means for providing a magnetic field, wherein a direction of the magnetic field is parallel to a direction of an effective field created by spin-orbit interactions in a qubit formed using the dopant dot so as to maximize a relaxation time of the qubit.

According to a fourth aspect, there is provided a method of fabricating a quantum processing system, the method comprising: exposing a semiconductor substrate to atomic hydrogen H to form a monolayer of H and passivating the surface of the semiconductor substrate: selectively desorbing H atoms from the passivated surface by the application of appropriate voltages and tunnelling currents to an STM tip, forming a plurality of patches in the H monolayer; wherein the orientation of the plurality of patches along a direction of the semiconductor lattice is selected to maximize relaxation time; incorporating a donor atom in each of the plurality of patches in the H monolayer, to form a donor molecule having a selected donor dot axis; and applying a magnetic field to the engineered quantum processing element, the direction of the magnetic field being perpendicular to the direction of the donor dot axis.

The method of fabricating further comprises: desorbing the hydrogen monolayer; and overgrowing the surface with a layer of the semiconductor.

In some embodiments, selectively desorbing H atoms further comprises desorbing H atoms to create one or more patches for creating one or more in-plane gates.

In some embodiments, the method further includes depositing one or more gates above the positions of the donor atoms.

In some embodiments, the method further comprises applying a voltage to the one or more gates to cause an electron to be confined in the donor molecule.

In some embodiments, the dopant dot comprises two donor atoms and the dopant dot axis is in a crystalline axis of the semiconductor substrate. In other embodiments, the dopant dot comprises two donor atoms and the dopant dot axis is in a crystalline axis of the semiconductor substrate. In such embodiments, the magnetic field is perpendicular to the crystalline axis of the semiconductor substrate.

In some embodiments, the dopant dot comprises two donor atoms and wherein the dopant dot axis is in a crystalline axis of the semiconductor substrate.

In some embodiments, the magnetic field is perpendicular to the dopant dot axis. In some examples, the magnetic field is approximately between 0.5 T-3 T.

In some embodiments, the dopant dot comprises three donor atoms.

The donor atoms of the first and/or second aspects may be phosphorus atoms.

Further aspects of the present disclosure and embodiments of the aspects summarised in the immediately preceding paragraphs will be apparent from the following detailed description and from the accompanying figures.

### BRIEF DESCRIPTION OF DRAWINGS

Features and advantages of the present invention will become apparent from the following description of embodiments thereof, by way of example only, with reference to the accompanying drawings, in which:

FIG. 1A shows a top view of an example donor qubit system.

FIG. 1B shows a side view of the example donor qubit system of FIG. 1A.

FIG. 2A shows an example 2P donor quantum dot system.

FIG. 2B shows another example 2P donor quantum dot system.

FIG. 3A is a schematic of one symmetry of a silicon quantum well.

FIG. 3B is a schematic of another symmetry of a silicon quantum well.

FIG. 3C is a schematic of yet another symmetry of a silicon quantum well.

FIG. 4A is a schematic of placement of donor atoms in a 2P quantum dot, wherein the donor atoms are placed along the crystalline axis.

FIG. 4B is a schematic of placement of donor atoms in a 2P quantum dot, wherein the donor atoms are placed along the crystalline axis.

FIG. 4C is a schematic of placement of donor atoms in a 2P quantum dot, wherein the donor atoms are placed along the crystalline axis.

FIG. 5A is a schematic showing spin relaxation mechanisms plotted in 3D with different magnetic field orientations, compared to measured results.

FIG. 5B is a schematic showing spin relaxation mechanisms plotted in 3D with the magnetic field orientation having an out of plane rotation of 135°.

FIG. 5C is a schematic showing spin relaxation mechanisms plotted in 3D with the magnetic field orientation having an out of plane rotation of 45°.

FIG. 5D is a schematic showing spin relaxation mechanisms plotted in 3D with the magnetic field orientation having an in plane rotation of 90°.

FIG. 6A shows 1/T₁ anisotropic function of a 2P donor molecule with [100], [001], [110], and inter-donor axis when the magnetic field orientation has an out of plane rotation of 135°.

FIG. 6B shows 1/T₁ anisotropic function of a 2P donor molecule with [100], [001], and inter-donor axis when the magnetic field orientation has an out of plane rotation of 45°.

FIG. 6C shows 1/T₁ anisotropic function of a 2P donor molecule with [100], [001], and inter-donor axis when the magnetic field orientation has an in plane rotation of 90°.

FIG. 7 is a plot showing the 1/T₁ B dependence with magnetic field pointing along the crystalline axis in a 2P molecule.

FIG. 8 shows a flowchart illustrating an example method for engineering a qubit system with optimal relaxation times.

### DETAILED DESCRIPTION

Generally speaking, an electron's orbital degree of freedom refers to the electron's motion around the nucleus of an atom or a molecule, and is characterized by its spatial distribution and energy level. The electron's motion in a given orbital is described by a wavefunction that gives the probability density of finding the electron at any point in space. Further, an electron's spin degree of freedom is an intrinsic property of an electron that describes its angular momentum in the absence of any external magnetic field. The electron spin can be visualized as a tiny magnet that points in a particular direction, either “up” or “down,” corresponding to its two possible spin states.

Spin-orbit interactions (SOI) refer to the interaction between the electron's spin degree of freedom and its orbital degree of freedom. These interactions have a number of consequences. For example, they can affect the energy levels of the electrons in the quantum dot. These interactions can also be used to manipulate the electron's spin in quantum information processing applications, such as in the creation and manipulation of spin qubits.

In semiconductor quantum dots, SOI can be enhanced when there is symmetry breaking of the system, leading to significant effects on the electron's spin. While strong SOI can facilitate electrically driven spin resonance (EDSR) for fast qubit operations, it also provides a mechanism for charge noise and phonons to couple to the electron spin and cause decoherence. Accordingly, inventors of the present disclosure have found that understanding the strength and limits of these interactions is important for spin qubit design and in particular relaxation times of qubits.

There are typically two main types of SOI in quantum dots: the Rashba effect and the Dresselhaus effect. The Rashba effect arises due to structural asymmetry such as the presence of external electric field, while the Dresselhaus effect arises due to the lack of inversion symmetry in the material in which the quantum dot is fabricated. Further, the impact of spin-orbit interactions varies with different types of nanostructures in silicon (Si) and can result in different forms of Dresselhaus and Rashba-like spin-orbit interactions.

One type of quantum computing system is based on the spin states of individual quantum processing elements, where the quantum processing elements may be electron spins, hole spins, or nuclear spins localized in a semiconductor chip. These electron, hole, and/or nuclear spins are confined either in gate-defined quantum dots or on donor or acceptor atoms that are positioned in a semiconductor substrate, and are referred to as quantum bits or qubits.

One particular donor based system includes phosphorus donor atoms in a silicon substrate forming donor dots. One or more electrons can then be loaded on to the donor dots. In such systems, it was found that anisotropic g-factor (i.e., ratio of the electron's magnetic moment to its angular momentum) modulation, which can arise due to a variety of factors such as strain or defects in the silicon crystal substrate and the six silicon conduction band valleys, causes spin-phonon relaxation. Further, another spin-orbit term that is defined by external electric and magnetic field contributions (H_{EB}) has been found to dominate spin relaxation processes of a single P donor atom in silicon, giving rise to relaxation times of approximately 40 ms at magnetic fields of 3.5 T along the crystal direction.

Recently, another type of qubit has gained popularity. This new qubit type includes n dopant atoms (where n>1). The n dopant atoms can be placed in silicon with atomic precision, e.g., using scanning tunneling microscopes (STM). The n dopant atoms form a single quantum dot or donor molecule. An electron or hole can then be loaded onto this n dopant atom quantum dot/donor molecule. Compared to single donor atom qubits, an electron or hole bound to an n dopant atom quantum dot has longer spin relaxation times due to stronger confinements of the electron which makes the excited valley states higher than those of single donor atom quantum dots and therefore harder to couple to a ground state as compared to single donor atom quantum dots qubits.

In a large processing system, having different number of dopant atoms in different qubits also gives rise to a highly tunable exchange interaction between the electrons bound by each qubit resulting in fast two qubit gate operations. In addition to the long lifetimes and highly tunable exchange, nP-mP double dopant dots allow single qubit control via EDSR as the electron moves between the two quantum dots with different hyperfine values, which is not the case in a 1P-1P system.

However, even with better relaxation times than their 1P counterparts, the relaxation times of nP quantum dots can be further improved.

Aspects of the present disclosure provide methods and systems for engineering the relaxation times of nP donor atom quantum processing systems. In particular, aspects of the present disclosure fabricate the donor atoms within the nP donor molecules along specific crystal lattice axes. Depending on the crystal lattice axis selected, the present disclosure engineers the relaxation times of the quantum dots by aligning an external magnetic field with the selected crystal lattice axis. In particular, the relaxation times of the qubits can be increased when the inter-donor axis or the axis between the donor dots is in some orientations (e.g., [100] or [110]) by aligning the external magnetic field perpendicular to an inter-donor axis/donor dot axis within the quantum dot.

Further, the relaxation times of a multi dopant atom molecule can be maximized by engineering the dopant atoms within the molecule in such a way that the effective magnetic field produced by the SOI in the molecule is parallel to the external magnetic field or the spin polarisation axis.

Further, in a multi-qubit system, some aspects of the present disclosure may utilize identical donor configuration for each qubit. In such systems, a qubit can be addressed uniquely by applying a local electric field to create a Stark shift on just that qubit. Other examples may utilize different donor configurations for different qubits in a quantum processing system.

The qubits of the present disclosure can be utilized as electron spin qubits—where quantum information is encoded in the spin of electron shared between the donor atoms. The qubits can also be utilized a nuclear spin qubits—where quantum information is encoded in the spin of any one of the donor atoms.

These and other aspects of the present disclosure will be described in detail in the following sections.

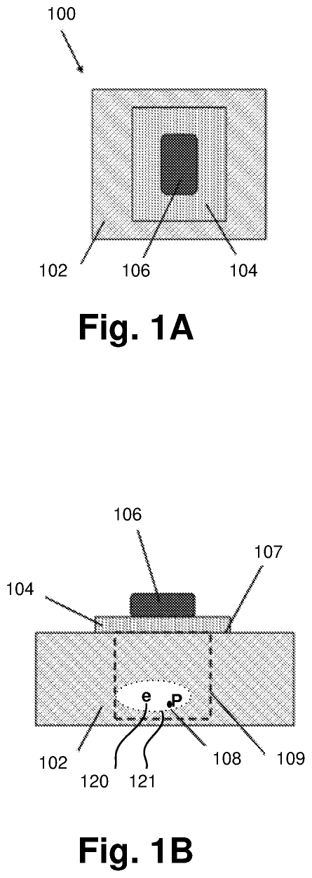

FIG. 1 illustrates an example spin qubit system 100 formed in a silicon substrate. FIG. 1A is a top view of the donor spin qubit system 100 and FIG. 1B is a side cross-section view. The donor spin qubit system 100 may be utilized in a quantum processor comprising a plurality of such qubit systems. As shown in the figure, the qubit system 100 is formed in a structure comprising a semiconductor substrate 102 and a dielectric 104. In this example, the substrate is ²⁸Silicon and the dielectric is silicon dioxide. Where the substrate 102 and the dielectric 104 meet an interface 107 is formed. In this example, it is a Si/SiO2 interface. To form a qubit, a donor atom 108 is located within the substrate 102 inside region 109 under a gate 106. The donor atom 108 can be introduced into the substrate using nano-fabrication techniques, such as hydrogen lithography provided by scanning-tunnelling-microscopes, or the industry-standard ion implantation techniques. In this example, qubit system 100 includes a single donor atom 108 embedded in the silicon crystal.

An electron 120 is then loaded onto the system 100 by a gate electrode 106. The physical state of the electron 120 is described by a wavefunction 121—which is defined as the probability amplitude of finding an electron in a certain position. Donor qubits in silicon rely on using the potential well naturally formed by the nucleus of the donor atom 108 to bind the spin of the electron 120.

The gate electrode 106 is located above region 109 and is operable to interact with the donor atom 108. For example, gate electrode 106 may be used to induce an AC electric field in the region between the interface 107 and the donor atom 108 to modulate a hyperfine interaction between the electron 120 and the nucleus of the donor atom 108. The electron wavefunction 121 is mediated by the local fields applied to the gate electrode 106. For example, local fields applied to the gate electrode 106 may pull the electron wavefunction 121 away from, or closer to, the donor atom 108.

In particular, the AC electric field can be used to control the quantum state of the qubit associated with the spin of the nucleus. Further, the AC electric filed works in synergy with an applied magnetic field—the magnetic field may be applied by a local antenna (not shown) positioned on the system 100 or a global antenna that may be positioned in the vicinity of the system 100 can provide a global oscillating magnetic field B₁ in a particular direction.

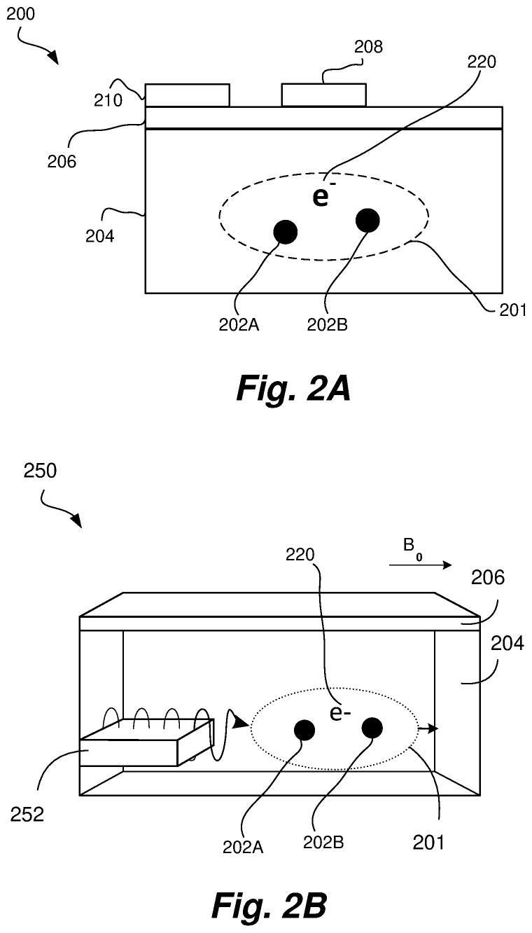

FIG. 2A shows another example qubit system v200. To form the qubit system 200, a plurality of donor atoms (two donor atoms 202A and 202B in this example) are located within a quantum dot 201 in a semiconductor substrate 204. In some examples, the donor atoms 202A, 202B are phosphorus atoms. In this example, qubit 200 includes two donor atoms 202. The silicon substrate 204 is topped by a barrier material/dielectric 206 such as silicon dioxide. Further, a gate 208 and an antenna 210 may be located on the dielectric 206 in a region above the quantum dot 201. Voltages may be applied to gate 208 to confine an electron 220 in the quantum dot 201. This electron 220 may be shared by the two donor atoms 202A, 202B. In one example, the donor molecule is a phosphorus (2P) donor molecule.

FIG. 2B shows another example qubit system 250. This is similar to the system shown in FIG. 2A. One difference being the placement of the gates. In FIG. 2A, the gate 208 was displayed as being placed on top of the dielectric 206. In this example, the gate 252 is located within the semiconductor substrate 202. Although FIGS. 2A and 2B show a single gate, multiple gates may be provided in some embodiments. Further, in some embodiments, the one or more gates 252 are placed substantially within the same plane as the donor dots 202. The in-plane gates may be connected to the surface of the substrate via metal vias (not shown). Voltages may be applied to gate electrode 252 to confine one or more electrons 220 in the quantum dot 201.

In some systems the in-plane gate electrode 252 is made of phosphorus doped silicon (˜0.25 ML doping density).

The donor atoms in the quantum dot 201 may be positioned such that they are in plane and the inter donor atom axis (i.e., the axis connecting the donor atoms) may be oriented along a crystal axis of the silicon substrate.

Further, the system 200 and/or 250 may include a local or global antenna that provides local or global oscillating magnetic field. The direction of the magnetic field may be selected such that it is perpendicular to the inter donor atom axis.

### Configuration of Donor Atoms in Quantum Dots

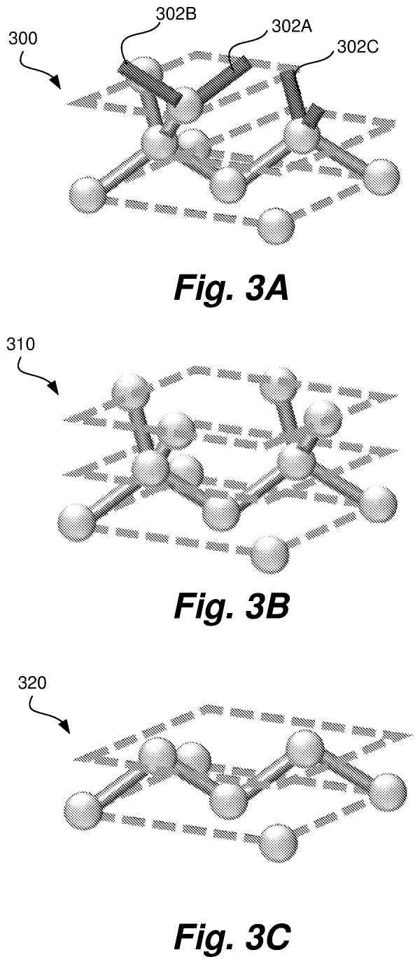

FIGS. 3A-3C depict silicon crystal lattice structures 300, 310, and 320 respectively, with different interface conditions and number of atomic layers. In particular, these figures illustrate that different interface conditions and number of atomic layers in a Si quantum well (i.e., a thin layer of silicon that is confined in two dimensions, such that electrons are restricted to move within the plane of the layer but are free to move in the third dimension) result in different symmetry groups, which allow different SOI.

In a Si quantum well, an ideal interface means the interfacial bonds lie in the same plane. The local symmetry is C₂ᵥ, i.e., the interface is invariant under 180° rotation about the z-axis or growth direction, and reflections about the (110) and (110) planes. In contrast, a non-ideal interface includes monoatomic fluctuations where the interfacial planes are shifted with respect to each other by one monolayer. In such cases, there may be two types of flat surfaces at the interface, with the bonds rotated by 90° since the two surfaces differ by one monolayer (see, e.g., the bonds 302A, 302B and 302C in FIG. 3A), and in average, it is difficult to distinguish between the direction and the direction, resulting in C₄ᵥ symmetry.

If one of the interfaces in a Si quantum well is ideal (C₂ᵥ) and the other one is non-ideal (C₄ᵥ), (e.g., the crystal lattice structure 300 depicted in FIG. 3A) then the overall symmetry of the system is still C₂ᵥ. Both Dresselhaus-like and Rashba-like SOI are invariant under such symmetry.

If both interfaces are ideal and the number of atomic layers in the quantum well is odd (e.g., the crystal lattice structure 310 as shown in FIG. 3B, which has three layers), then the system contains symmetry operations 180° rotations about the x, y and z-axis, reflections about the (110) and (110) planes, and S₄ operator −90° rotation with respect to the axis, followed by a reflection in the horizontal plane. The corresponding symmetry group is D_{2d} in such systems. Compared to the C₂ᵥ group, the Rashba-like spin-orbit interaction is not invariant under the S₄ operator in the D_{2d} symmetry group. Therefore only Dresselhaus-like SOI are allowed in such cases.

To make the symmetry of the system even higher, if both interfaces are ideal and with even number of layers in the quantum well (e.g., see the crystal lattice structure 320 in FIG. 3C, which has two layers), then the symmetry group (D₂ₕ) contains a space inversion operator which prohibits both the Dresselhaus-like and Rashba-like SOI.

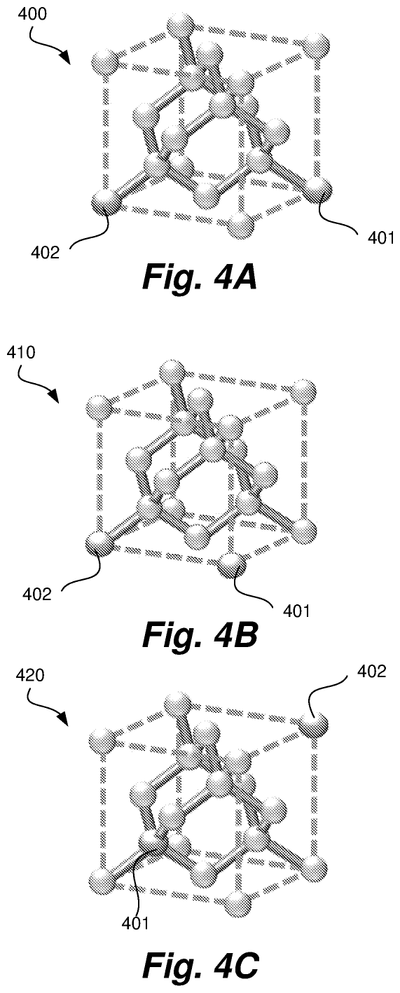

FIGS. 4A-4C show placement of donor atoms in a 2P quantum dot along different silicon crystal lattice axes. In particular FIG. 4A shows placement of donor atoms 401 and 402 along the 110 axis, FIG. 4B shows placement of donor atoms 401, 402 along the 100 axis and FIG. 4C shows placement of the donor atoms 401, 402 along the 111 crystal axis of the crystal lattice structures 400, 410 and 420, respectively.

When placing the donors atoms of an n donor atom quantum dot (e.g., as shown in FIGS. 1A and 2B) along the crystalline axis, the system is invariant under 180° rotation about the axis, and reflections about the (110) and (110) planes (see FIG. 4A). The symmetry group is therefore C₂ᵥ, allowing both Dresselhaus and Rashba SOI.

If the two donors are separated along the crystalline axis (as shown in FIG. 4B), the symmetry is identical to odd layer quantum wells with ideal interfaces-D_{2d}, allowing only the Dresselhaus spin-orbit.

If the two donors are separated along the crystalline axis (as shown in FIG. 4C), e.g., with separation distance (N±0.25, N±0.25, N±0.25)a₀, where N is an integer and a₀=0.543095 is the Si lattice constant, then the system is invariant under operations such as C₃ (120° rotations about the axis), Od (reflection about the (110), (011) and (101) planes) and inversion (about the midpoint of the two donors). The symmetry group is D_{3d} [46]. In this specific donor atom configuration, as the system possesses an inversion center, both Dresselhaus and Rashba SOI will not be allowed.

As the configuration of donor atom placements in the crystal lattice affects the SOI, the inventors of the present disclosure have determined that spin qubits can be designed with different SOI by placing the donor atoms 202A, 202B of a quantum dot 201 at specific atomic locations with STM techniques.

### Spin Relaxation Mechanisms

As discussed previously, in the presence of SOI, both phonon and charge noise can impact the electron spin and cause spin-relaxation. In addition, hyperfine interaction (i.e., the interactions between the qubit and the surrounding environment) can also mix the spin and orbital degrees of freedom, together with phonon or charge noise from a spin-relaxation channel.

There are a number of specific SOI and hyperfine interaction based spin relaxation mechanisms that can affect a 1P 100 and nP quantum dot system 200. The following subsections describe all the possible spin relaxation mechanisms. In each subsection, the spin-relaxation mechanisms that impact the electron bound by single donors is reviewed first followed by extending it to an example nP system (i.e., a 2P donor quantum dot system 200).

### Bulk Spin-Orbit Interaction Mediated Phonon Relaxation

In a single donor, the g-factor (i.e., the gyromagnetic ratio of the donor atom, which describes the strength of the interaction between the donor atom's spin and an external magnetic field) is modulated by the bulk silicon SOI, with the resulting g-tensor different between different Si conduction band valleys. The g-factor determines the sensitivity of the qubit to external magnetic fields. Specifically, the g-factor determines the energy splitting between the qubit's different spin states in the presence of a magnetic field. The g-tensor is a mathematical object that describes the relationship between an external magnetic field and the magnetic moment of the donor atom. In particular, it determines the strength and direction of the magnetic field required to manipulate the qubit's spin state.

The deformation potential tensor (a material parameter that describes the relationship between a crystal lattice deformation and the resulting changes in the energy of an electron or hole in a quantum dot) from the electron-phonon Hamiltonian behaves in a similar way to the g-tensor, and together they form the valley repopulation spin relaxation mechanism. The valley repopulation mechanism couples the ground state (often labelled as A₁) with higher valley states with +/−valleys (X and X̅) having the same phase (labelled as E), but not the valley states with +/−valleys having opposite phase (labelled as T₂). This is because both the g-tensor and the deformation potential tensor cancel out when the +/−valleys have opposite phase. The valley “repopulates” as the ground A₁ state with equal valley weights (α_{X}=α_{Y}=α_{Z}=α_{\hat{X}}=α_{Ŷ}=α_{\hat{Z}}=1/\sqrt{6}) mixes with the higher doublet E states with different valley weights (α_{X}=α_{\hat{X}}=−/\sqrt{12}, =α_{Y}=α_{Y}=−1/\sqrt{12}, α_{Z}=α_{\hat{Z}}=2/\sqrt{12} and α_{X}=α_{\hat{X}}=½, =α_{Y}=α_{Ŷ}=−½, α_{Z}=α_{\hat{Z}}=0).

In addition to valley repopulation mechanism, single valley effect originates from off-diagonal phonon strain which couples Si conduction band with higher-lying bands in each valley. In a 2P quantum dot 200, the symmetry group is different from 1P (T_{d}), and the A₁, T₂ and E representations do not apply. For example, the X valley weight will be different from the Y and Z valley weights for 2P separated along the crystalline axis. However valley repopulation and single valley effect are still present as the phonon strain mixes between the 2P valley states (with +/−valleys having the same phase) and the conduction bands in each valley.

### H_{EB} Spin-Orbit Interaction Mediated Phonon Relaxation

A spin-orbit term that couples the external electric (E) and magnetic (B) fields, H_{EB}, together with phonons through valley repopulation (coupling the A₁ state with the E state), has been found to dominate the spin-relaxation processes in a single P donor in Si under applied gate bias. The H_{EB} Hamiltonian

$${H}_{EB} = {( E \times B )}^{+} \cdot \overleftrightarrow{C} \cdot σ \qquad ( 1 )$$

$$where$$

$${( E \times B )}^{+} = ( {E}_{y} {B}_{z} + {E}_{z} {B}_{y} , {E}_{z} {B}_{x} + {E}_{x} {B}_{z} , {E}_{x} {B}_{y} + {E}_{y} {B}_{x} ) \qquad ( 2 )$$

$$and$$

$$\overleftrightarrow{C} ( Xvalley ) = [ \begin{matrix}{C}_{l} & & \\ & {C}_{t} & \\ & & {C}_{t}\end{matrix} ] \qquad ( 3 )$$

is also allowed in a system of 2P donor atoms separated by the and crystalline axis, with symmetry group D_{2d} and C₂ᵥ, respectively, but not the 2P separated along the crystalline axis with D_{3d} symmetry, since H_{EB} is not invariant under the inversion operator. The H_{EB} mediated phonon relaxation will therefore be present in 2P separated along the and crystalline axis, but not the case for the crystalline axis.

### Dresselhaus Rashba Spin-Orbit Interactions Mediated Phonon Relaxation

While phonons couple between the A₁ and E states in single donors, Dresselhaus/Rashba SOI cannot couple the same states and form a relaxation channel with phonons. This is because the matrix element of the operator kₓ in the Dresselhaus and Rashba Hamiltonian, ((kₓ)₀ₙ=imE₀ₙ x₀ₙ/h²), where m is the electron mass and E₀ₙ is the energy gap between the ground 0 state and the nth excited state, depends on the dipole moment x₀ₙ. The dipole moment between the A₁ and E states, is however negligible (x_{A}_{₁}_{E}= [symbol] X+X̅|x|X+X̅ [symbol] =0. The dipole moments between the A₁ and T₂ states x_{A1T2}= [symbol] X+X̅|x|X−X̅ [symbol] , however, can be much larger. Nonetheless as mentioned in the previous section, phonons cannot couple between the A₁ and T₂ states since the T₂ states have opposite phase for the +/−valleys. Therefore, as opposed to mixing with valley states, mixing with higher orbital states is required for Dresselhaus and Rashba spin-orbit interactions to mediate phonon relaxation. However, the electron-phonon coupling for mixing the ground state with higher orbital states is one order higher in perturbation compared to mixing the ground state with valley states.

Accordingly, even in the presence of Dresselhaus and Rashba SOI, spin-valley mixing is only possible when there is disorder from the interface and the valley states mix with the orbital states. Coming from higher-order perturbation, the corresponding relaxation rate from Dresselhaus/Rashba SOI mixing the ground spin states with higher-orbital states is much smaller than bulk spin-orbit mediated phonon relaxation rate and H_{EB} mediated phonon relaxation rate. This is the case in both single donors and multi-donor systems.

### Bulk Spin-Orbit Interaction Mediated Charge Noise Relaxation

As mentioned in the last subsection, the dipole moments between the A₁ and E states are negligible, but the dipole moments between the A₁ and T₂ states are much larger. Charge noise can therefore couple between the A₁ and T₂ states, whereas the bulk SOI or g-tensor can only couple the A₁ and E states. Charge noise therefore cannot repopulate the valleys and form a relaxation channel with bulk spin-orbit interaction in both single donors and multi-donor systems. There is also no coupling to higher orbital states since g-tensor can only mix between same orbital different valley states, but not different orbital states.

### HEB Spin-Orbit Interaction Mediated Charge Noise Relaxation

For the same reason as the bulk spin-orbit interaction case, charge noise cannot form a spin-relaxation channel with HEB by coupling to the excited valley states since the charge noise cannot repopulate the valleys. Nevertheless, charge noise can couple the ground spin states (|0↑ [symbol] and |0↓ [symbol] ) directly by transforming the electric field fluctuation to a magnetic noise through the Hamiltonian of H_{EB} and form a relaxation channel.

### Dresselhaus Rashba SOI Mediated Charge Noise Relaxation

Just as H_{EB}, the electric field induced Rashba SOI ((E×k)·σ) also directly depends on the electric fields. However, since the k or dipole moment is zero between the same ground state, charge noise cannot couple the ground spin states |0↑ [symbol] and |0↓ [symbol] directly through the electric field induced Rashba SOI and form a relaxation channel. Coupling to higher valley/orbital states is required for the electric field induced Rashba SOI to mediate charge noise relaxation.

While the electric field induced Rashba spin-orbit interaction ((E×k)·σ) is present in both single donors and 2P donors, Rashba-like spin-orbit (k_{xσy}−k_{yσx}) only presents in systems such as 2P separated along the [110] crystalline axis. This is because the Rashba-like SOI is not invariant under the S₄ operator in the 1P T_{d} group and the 2P D_{2d} group (when the two donors are separated along the [100] crystalline axis), also the inversion operator in the D_{3d} group (when the two donors are separated along the [111] crystalline axis with an inversion center).

Dresselhaus-like and Rashba-like spin-orbit interactions do not have a strong dependency on the electric field. Therefore charge noise cannot be directly transformed into magnetic noise by coupling the ground spin states through Dresselhaus-like and Rashba-like SOI. However, both Dresselhaus-like/Rashba-like SOI and charge noise depend on dipole moments and can couple the ground state with the valley states with +/−valleys having opposite phase in a 2P system, which gives non-zero dipole moments, therefore forming a relaxation channel.

### Hyperfine Interaction Mediated Phonon Relaxation

Apart from the SOI, hyperfine interactions between the electron spin bound by donors and the donor nuclear spins needs to be studied, as this can also mediate spin-relaxation. While hyperfine mediated phonon relaxation is very weak for single donors, the hyperfine interaction is much stronger for tightly bound 2P donors since the electron density at the donor sites is much larger.

The hyperfine mediated phonon relaxation has therefore been found to dominate at magnetic fields around B=1.5 T in multi-donor systems.

### Hyperfine Interaction Mediated Charge Noise Relaxation

In a 1P system, hyperfine interaction has a quadratic dependence on the Stark effect since the symmetric electron wavefunction is difficult to move by electric fields. Charge noise therefore can hardly affect the electron spin through hyperfine interactions in a 1P system. In contrast, in a 2P system, the hyperfine interaction has a linear Stark coefficient, and therefore responds linearly to charge noise. However, without changing the nuclear spin orientation, the magnetic noise generated by charge noise through hyperfine interaction points along the spin polarisation axis, therefore shortening the T₂/T₂ decoherence/dephasing times and not the T₁ relaxation time.

As discussed above, the possible dominating spin-relaxation mechanisms in a 2P system are: bulk SOI mediated phonon relaxation, H_{EB} mediated phonon relaxation, H_{EB} mediated charge noise relaxation, Dresselhaus/Rashba-like spin-orbit mediated charge noise relaxation and hyperfine interaction mediated phonon relaxation. While the first two spin-orbit mediated phonon relaxation mechanisms have a B⁵ dependency on the 1/T₁ relaxation rate, the two spin-orbit mediated charge noise relaxation rates have linear B dependencies, and the hyperfine mediated phonon relaxation rate has a B³ dependency. While phonon relaxation mechanisms dominate at magnetic fields B>3T, at low magnetic fields around B =1.5 T other relaxation mechanisms such as spin-orbit mediated charge noise relaxation and hyperfine mediated phonon relaxation are more likely to dominate.

Different physical relaxation mechanisms have different dependencies on the magnetic field. For example, B³ is related to hyperfine mediated relaxation times and B⁵ is related to spin orbit relaxation. By measuring B field dependency experimentally, which relaxation effect is dominant can be determined.

### Theory v Experiments

A way to reveal the nature of the spin-orbit interaction is through observing the 1/T₁ anisotropy, i.e. the change in T₁ times with external magnetic field orientations. 1/T₁ anisotropy may be measured in a 1P donor dot system with an external electric field pointing in the [010] crystal axis. In such a case, the T₁ time is longest (T1=1.25 s) when the external magnetic field also points along the [010] crystalline axis, which is explained by the H_{EB} spin-orbit interaction mediated phonon relaxation since H_{EB} is zero when both the external electric and magnetic fields are in the [010] crystal direction.

Measurements of the T₁ times of a multi-donor dot in Si is performed with the device patterned using STM (e.g., using system 200). Using a suitable readout technique that allows low magnetic fields (B<1.5 T) with high readout fidelity, the angle of the external magnetic field is varied with respect to the Si crystalline axis at B=1.5 T to observe anisotropy in T₁.

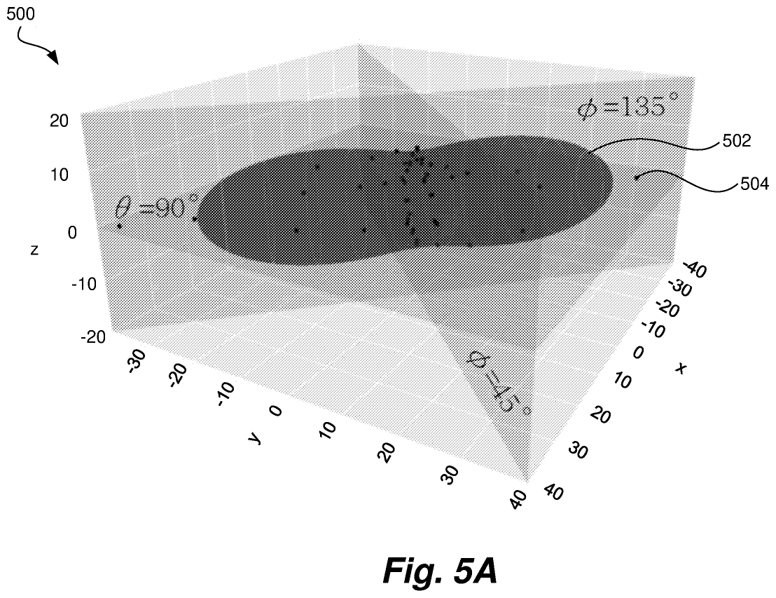

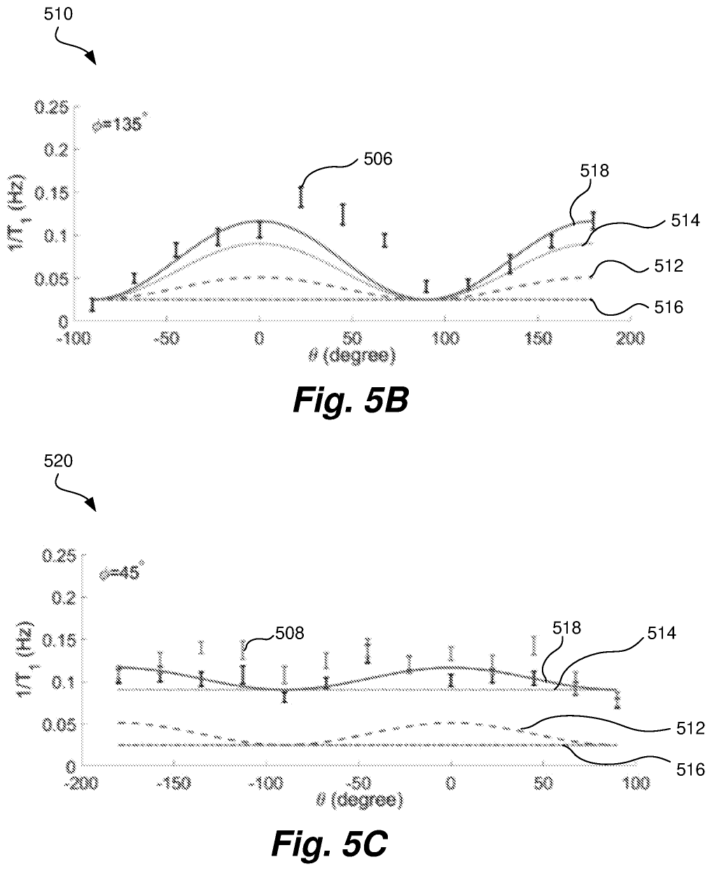

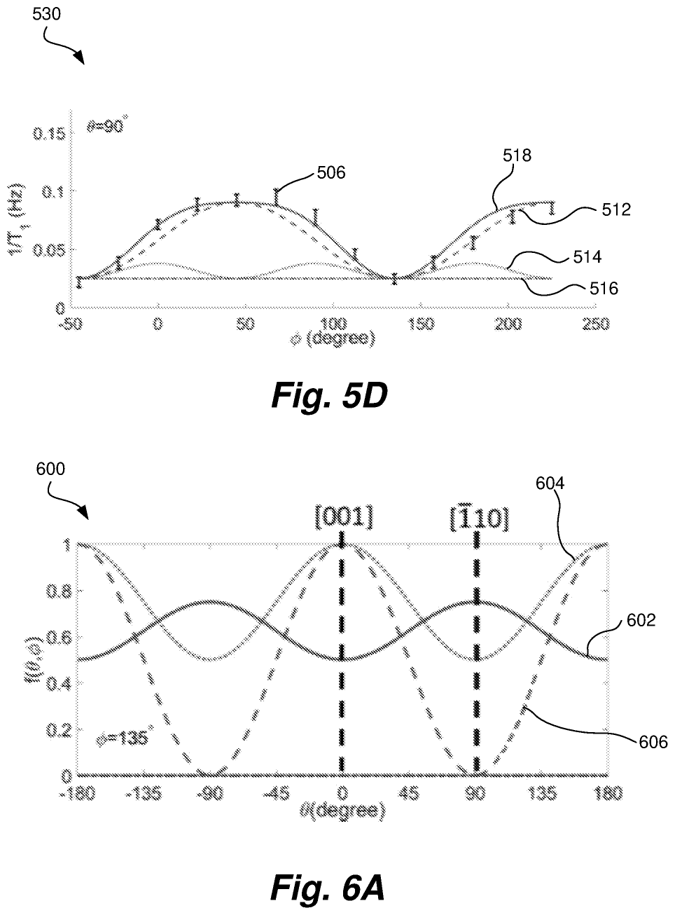

FIG. 5A is a schematic 500 showing spin relaxation mechanisms plotted in 3D with different magnetic field orientations (surface 502), compared to measured results (dots 504). FIG. 5B is a chart 510 showing spin relaxation mechanisms plotted in 3D with the magnetic field orientation having an out of plane rotation of 135°. FIG. 5C is a chart 520 showing spin relaxation mechanisms plotted in 3D with the magnetic field orientation having an out of plane rotation of 45°. FIG. 5D is a chart 530 showing spin relaxation mechanisms plotted in 3D with the magnetic field orientation having an in plane rotation of 90°.

The measured data is shown by the dots 504 in FIG. 5A and the black and grey error bars 506 and 508, respectively, in FIGS. 5B-5D. As can be seen from the plots in FIGS. 5A-5D, the measured 1/T₁ has maximum values when the magnetic field direction is parallel to [110] and minimum values when the magnetic field direction is parallel to [11̅1]. When the two P donors are separated along the [110] crystalline axis, the resulting effective magnetic field produced by either the Dresselhaus-like term or the Rashba-like term points along the [11̅0] crystalline axis, since [symbol] for [110]-separated donors.

Therefore when this effective magnetic field produced by the SOI is perpendicular to the external magnetic field or the spin polarisation axis (the plane with φ=45°, shown in FIG. 5C), the electron spin has maximum spin-orbit mixing and spin relaxation, which results in a maximum 1/T₁.

However when both the effective magnetic field produced by the SOI and the external magnetic field point in the same direction (along [11̅0], or φ=135° and θ=90°, shown in FIGS. 5B and 5D), then there is no spin-orbit interaction mixing and therefore minimal relaxation so T₁ is the longest (T₁=40 s).

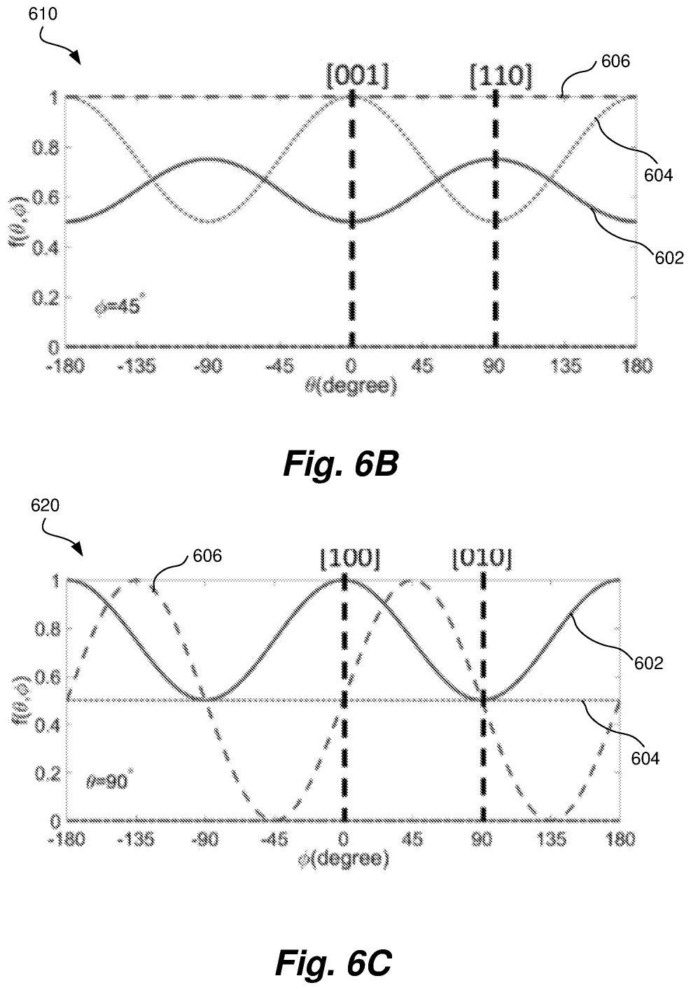

FIG. 6 shows the 1/T₁ anisotropy function of 2P molecules separated along (line 602), (dotted line 604), (dashed line 606) and (purple dash-dotted line) crystalline axis. In particular, FIG. 6A is a plot 600 showing 1/T₁ anisotropic function of a 2P donor molecule with [100], [001], [110], and inter-donor axis when the magnetic field orientation has an out of plane rotation of 135°, FIG. 6B is a plot 610 showing 1/T₁ anisotropic function of a 2P donor molecule with [100], [001], [110], and inter-donor axis when the magnetic field orientation has an out of plane rotation of 45°, and FIG. 6C is a plot 620 showing 1/T₁ anisotropic function of a 2P donor molecule with [100], [001], [110], and inter-donor axis when the magnetic field orientation has an in plane rotation of 90°.

This anisotropy function results from Dresselhuas-like or both Dresselhaus and Rashba-like spin-orbit mediated charge noise relaxation. The anisotropy function is determined by the form of the SOI as well as the ground and excited valley states of the 2P quantum dot 200 coupled by the SOI. Compared to FIG. 5A-5D, only the [110]-separated donors can explain the measured anisotropy (dashed lines 606 in both FIGS. 6A-6C and FIGS. 5B-D).

In addition to the Dresselhaus/Rashba-like spin-orbit mediated charge noise relaxation, H_{EB} mediated charge noise relaxation, and the hyperfine mediated phonon relaxation is also considered. There are therefore three fitting parameters representing the strength of each mechanism.

The fitted results are shown in FIG. 5B-D, with the Dresselhaus/Rashba-like spin-orbit mediated charge noise relaxation shown by lines 512, the H_{EB} mediated charge noise relaxation shown as the dotted lines 514, the hyperfine mediated phonon relaxation shown as the dash-dotted lines 516, and the total relaxation rate obtained from summing up all three relaxation mechanisms shown as the solid lines 518 in FIG. 5B-D.

Different spin-relaxation mechanisms give different B dependencies to the relaxation rate. B dependencies refer to the dependence of qubit relaxation times on the strength and orientation of an external magnetic field (B-field). There are different types of B-field dependencies that can affect the relaxation times of qubits. These include, linear B dependencies and quadratic B dependencies. In linear B dependencies, the relaxation time of the qubit decreases linearly with increasing B field strength. This can arise due to coupling of the qubit's spin to external magnetic fields, such as the Earth's magnetic field, or due to intrinsic properties of the qubit material. In quadratic dependencies, the relaxation time of the qubit decreases quadratically with increasing B-field strength. This can arise due to coupling of the qubit's spin to magnetic impurities or defects in the qubit material.

Spin-orbit mediated phonon relaxation, for example, gives a B⁵ dependency in one to few closely packed donor atoms, where the phonon part contributes to B³ and the spin-orbit interaction contributes to B². The hyperfine mediated phonon relaxation gives only a B³ dependence from phonons, since the hyperfine interaction does not depend on the external magnetic fields. In precision placed donor devices, the noise spectrum shows a 1/f^{α} behaviour, where the value of a (the power dependence of noise to frequency) can vary between 1 and 2. For simplicity a is assumed to be 1, therefore the noise spectrum gives a 1/B dependency to 1/T₁. H_{EB} gives a B² dependence to 1/T₁, and together with 1/f charge noise 1/T₁ has a total linear B dependence. Dresselhaus/Rashba-like spin-orbit interactions also give a B² dependence to 1/T₁, together with charge noise, give 1/T₁ a linear B dependency. Even though Dresselhaus/Rashba-like spin-orbit Hamiltonian (H_{D}=α_{D}(kₓσₓ−k_{y}σ_{y}), H_{R}=α_{R}(kₓσ_{y}−k_{y}σₓ) do not depend on external magnetic field explicitly, if a Schrieffer-Wolff transformation e^{S}Hₛₚᵢₙ e^{-S} is performed on the spin Hamiltonian Hₛₚᵢₙ=H_{Zeeman}+H_{D}+H_{R}, where S=e^{-in·σ}, where

$$n = \frac{x}{{l}_{D}} - \frac{y}{{l}_{R}} , \frac{x}{{l}_{R}} - \frac{y}{{l}_{D}} ,$$

and l_{D/R} is the spin-orbit length, which is related to the spin-orbit strength through

$${l}_{D / R} = \frac{{ℏ}^{2}}{2 m {α}_{D / R}} ,$$

the effective magnetic field, B_{eff} is obtained as B_{eff}=B×n.

This effective magnetic field is then explicitly dependent on the external magnetic field B. In addition to the T₁ anisotropy, the 1/T₁ B dependency is measured, fixing the magnetic field direction to the crystal axis (0=90° and φ=) 45° to check the theory.

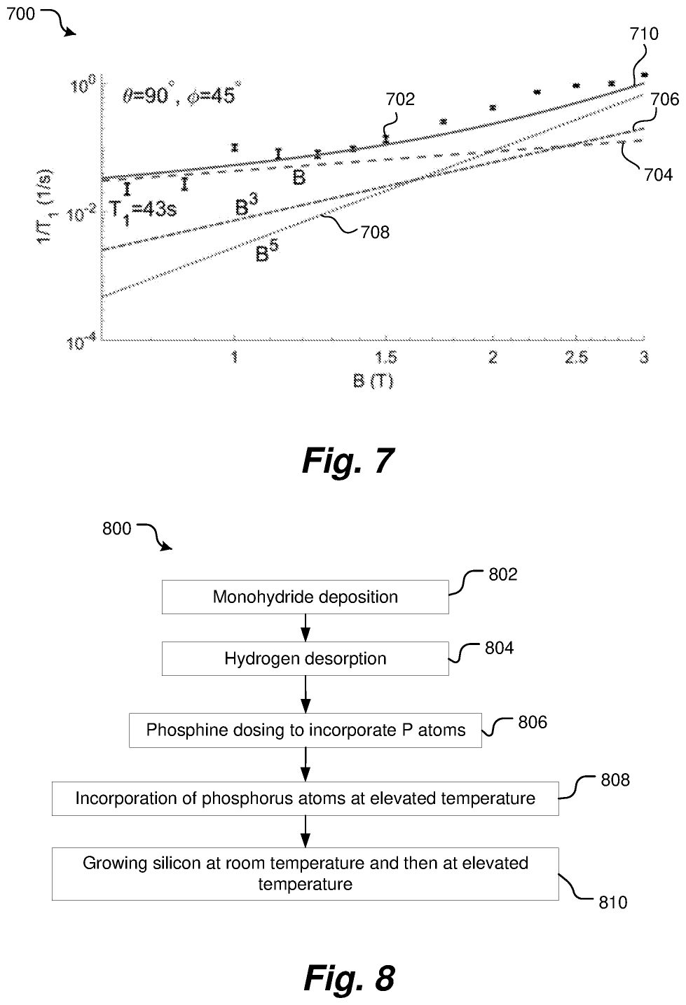

FIG. 7 is a plot 700 showing this 1/T₁ B dependence with magnetic field pointing along the crystalline axis in a 2P molecule.

The black error bars 702 shown in FIG. 7 represent the measured data. Even though as shown in FIG. 5 at this angle (B∥ [110]) with B=1.5 T the T₁ time is shortest (T₁˜11 s), magnetic fields as low as B=0.75 T can be used to obtain longest T₁₌₄₃s.

Longest T₁ of 15 s was observed previously in the same 2P donor dot, with B=1.5 T and magnetic field angle φ=−68° and θ=90°. Different from FIG. 7 where the measured 1/T₁ mainly follows a linear B dependence, previously the measured 1/T₁ B dependence was B³ at low magnetic field regimes (B<3 T). This discrepancy is because the two measurements were done at different magnetic field angles. When the magnetic field is parallel to [110](φ=45°, the impact of SOI is the largest, however when φ=−68°(equivalent to φ=112°, the impact of spin-orbit mediated relaxation is much smaller (see the black bars 506 in FIG. 5D), hence the hyperfine mediated phonon relaxation dominates in the latter case.

Therefore when the magnetic field direction is parallel to (φ=) 45°, 1/T₁ is dominated by spin-orbit mediated charge noise relaxations which follow a linear B dependency, whereas when φ=−68°, 1/T₁ is dominated by hyperfine mediated phonon relaxation which follows a B³ dependency.

In FIG. 7, the dashed line 704 represents the sum of Dresselhaus-like/Rashba-like/H_{EB} spin-orbit mediated charge noise induce spin relaxation, which has a linear B dependency, with the magnitude taken from the fitting results of T₁ anisotropy data. The dashed-dotted line 706 is the hyperfine mediated phonon relaxation, which follows a B³ dependency, with the magnitude again taken from the T₁ anisotropy fit. The dotted line 708 represents the B⁵ spin-orbit mediated phonon relaxation. The magnitude of the spin-orbit mediated phonon relaxation is estimated with a higher B field range (B>1.5 T) and a different orientation (φ=−68° and θ=90° in the same dot (2P) and same system 200. A sum of all the relaxation mechanisms is represented by the solid line 710, which matches well with the experimental data (black error bars 506) without any fitting involved.

### Estimate the SOI Strength

To estimate the Dresselhaus/Rashba/H_{EB} SOI strength of the 2P donor molecule in Si, 1/f charge noise from surface oxide traps is estimated, then the noise amplitude at the donor dot location in the system is extracted. Then by comparing to the spin-orbit mediated charge noise induced 1/T₁, the corresponding spin-orbit strength can be obtained.

The noise spectrum of the donor dot (S=S₀/f^{α}) is also measured by tracking the nearby SET Coulomb peak position, which results in S₀=13(μeV)²/Hz and α=1.22.

To obtain the electric field fluctuation at the donor dot site a model is developed to capture the fields generated from two-level fluctuators. All the fluctuating electric fields from the two-level fluctuators are summed (around 800 flip-flopping dipoles as electrons jump between surface oxide traps with an average separation of 15 nm with random telegraph signals) in a flat region (600 nm×600 nm×2 nm) 40 nm above the donor dot plane. S₀ and α depend to some degree on the locations of the oxide traps. The trap locations can be generated such that the resulting S₀˜13(μeV)2/Hz and α˜1.22. Therefore these locations of the oxide traps in the model mostly resemble the trap locations in the system.

From such a model, the electric noise spectrum amplitude is obtained as S_{EO}=1.7e−6 (MV/m)² at 1 Hz.

Given the noise amplitude, the corresponding 2P spin-orbit strength was extracted from the 1/T₁ anisotropy fitting results. The combined Dresselhaus and Rashba-like spin-orbit interactions were extracted by comparing to the dashed line 512 in FIG. 5B, which corresponds to the Dresselhaus/Rashba spin-orbit interactions mediated charge noise relaxation rate. The H_{EB} spin-orbit interaction was extracted from comparing to the dotted line 514 in FIG. 5B, which corresponds to the H_{EB} spin-orbit interaction mediated charge noise relaxation rate. The 2P Dresselhuas/Rashba-like spin-orbit strength (α=1646 ×10⁻¹³ eV cm) is around 1.8 times larger compared to the strength of electric field induced Rashba spin-orbit in single donors (α=905×10⁻¹³ eV cm at E=1 MV/m), one-order of magnitude larger than the spin-orbit interactions in a MOS-based quantum dot (α=178 ×10⁻¹³ eV cm), and two-orders of magnitude larger than the spin-orbit interactions in a SiGe quantum dot (a =9.4×10⁻¹³ eV cm). The 2P H_{EB} strength (C=C₁−Cₜ=6.76×10⁻¹⁴ e m/T, see eq. 3) is 1.15 times larger than the 1P H_{EB} strength (C=5.86×10⁻¹⁴ e m/T). The larger spin-orbit interaction in 2P molecules is likely due to the stronger confinement compared to single donors and quantum dots.

### EXAMPLE METHOD

FIG. 8 shows a flowchart illustrating an example method 800 for engineering a qubit system (e.g., including multiple 2P molecules 200) for optimal relaxation times according to aspects of the present disclosure.

Initially, a clean Si 2×1 surface is formed in an ultra-high-vacuum (UHV) by heating to near the melting point. This surface has a 2×1 unit cell and consists of rows of o-bonded Si dimers with the remaining dangling bond on each Si atom forming a weak-bond with the other Si atom of the dimer of which it comprises.

Next, at step 802, (i.e., monohydride deposition) the clean Si 2×1 surface is exposed to atomic H to break the weak Si π-bonds, allowing H atoms to bond to the Si dangling bonds. Under controlled conditions a monolayer of H can be formed with one H atom bonded to each Si atom, satisfying the reactive dangling bonds, effectively passivating the surface.

Next, at step 804 (i.e., hydrogen desorption), an STM tip is used to selectively desorb H atoms from the passivated surface by the application of appropriate voltages and tunneling currents, forming a pattern in the H resist.

It will be appreciated that H atoms are desorbed from precise locations and in precise directions such that nP quantum dots 200 can be placed in precise orientations to achieve high Stark shifts in the presence of electric fields. For example, if an nP quantum dot 200 is to include two donor atoms spaced 12 lattice sites or 4.6 nm apart along the direction, the STM tip may be used to desorb six hydrogen atoms at one location along a dimer row and then desorb six additional hydrogen atoms 4.5 nm apart along the same dimer row from the first location.

This process is repeated to create positions for other donor molecule sites. In this way regions of bare, reactive Si atoms are exposed along dimer rows, allowing the subsequent adsorption of reactive species directly to the Si surface. Further, it will be appreciated that at step 804, each of the fabricated quantum dots can have the same number of donor atoms or different number of donor atoms. Further, the donor atoms in each of the fabricated quantum dots can be oriented along the same crystal axis or different crystal axes without departing from the scope of the present disclosure.

Returning to FIG. 8, at step 806 (i.e., PH3 dosing), phosphine (PH3) gas is introduced into the vacuum system via a controlled leak valve connected to a specially designed phosphine micro-dosing system. The phosphine molecule bonds strongly to the exposed Si surface, through the holes in the hydrogen resist). As noted previously, at a particular donor site, a phosphine molecule may bond with any one of the exposed silicon dimers.

Subsequent heating of the STM patterned surface for crystal growth causes the dissociation of the phosphine molecules and results in the incorporation of P into the exposed layer of Si. It is therefore the exposure of an STM patterned H passivated surface to PH3 that is used to produce the required donor molecules.

The hydrogen may then be desorbed, at step 808, before overgrowing the surface with silicon at room temperature, at step 810. An alternative is to grow the silicon directly through the hydrogen layer. The surface is then rapidly annealed.

Silicon is then grown on the surface at elevated temperature. In one example, approximately 50±5 nm of epitaxial silicon is grown at a temperature of 250° C.

Once the required amount of silicon is grown, a barrier may be grown. Finally a microwave antenna may be aligned on the surface using electron beam lithography. Using etched registration markers, the antenna is aligned at a lateral distance of 300±50 nm from the buried donor molecules to produce an oscillating magnetic field B₁.

Gates may be positioned on the silicon substrate along with the antenna. Alternatively, gates may be positioned in the same plane as the quantum dots. In such examples, the gates may be formed of Si:P during the H desorption phase.

Further, although the quantum processing systems described herein have been shown with gate electrodes for controlling corresponding qubits, these may not always be necessary. In other embodiments and examples other control means may be utilized without departing from the scope of the present disclosure.

The present embodiments are, therefore, to be considered in all respects as illustrative and not restrictive.

As used herein, except where the context requires otherwise, the term “comprise” and variations of the term, such as “comprising”, “comprises” and “comprised”, are not intended to exclude further additives, components, integers or steps.

Reference to any prior art in the specification is not an acknowledgment or suggestion that this prior art forms part of the common general knowledge in any jurisdiction or that this prior art could reasonably be expected to be understood, regarded as relevant, and/or combined with other pieces of prior art by a skilled person in the art.

1. (canceled)

2. A quantum processing system comprising:
a semiconductor substrate;
a dielectric material forming an interface with the semiconductor substrate;
a dopant dot formed in the semiconductor substrate comprising a plurality of dopant atoms and one or more electrons/holes confined within the dopant dot, wherein the dopant atoms of the dopant dot are positioned in the semiconductor substrate to have a particular dopant dot axis such that a relaxation time of the electron/hole is maximized.

3. The quantum processing system of claim 2, further comprising a means for providing a magnetic field that is applied in a particular direction with respect to the dopant dot axis such that the relaxation time of the electron/hole is maximized.

4. The quantum processing system of claim 2, wherein the dopant dot comprises two donor atoms and wherein the dopant dot axis is in a crystalline axis of the semiconductor substrate.

5. The quantum processing system of claim 2, wherein the dopant dot comprises two donor atoms and wherein the dopant dot axis is in a crystalline axis of the semiconductor substrate.

6. The quantum processing system of claim 5, wherein the magnetic field is perpendicular to the crystalline axis of the semiconductor substrate.

7. The quantum processing system of claim 2, wherein the dopant dot comprises two donor atoms and wherein the dopant dot axis is in a crystalline axis of the semiconductor substrate.

8. The quantum processing system of claim 7, wherein the magnetic field is perpendicular to the dopant dot axis.

9. The quantum processing system of claim 2, wherein the magnetic field is approximately between 0.5 T-3T.

10. The quantum processing system of claim 2 wherein the dopant dot comprises three donor atoms.

11. The quantum processing system of claim 2, wherein the donor atoms are phosphorus atoms.

12. A quantum processing system comprising:
a semiconductor substrate;
a dielectric material forming an interface with the semiconductor substrate;
a dopant dot comprising a plurality of dopant atoms and one or more electrons/holes confined within the dopant dot, wherein the dopant atoms of the dopant dot are positioned in the semiconductor substrate to have a particular inter donor atom axis; and
a means for providing a magnetic field, wherein a direction of the magnetic field is parallel to a direction of an effective field created by spin-orbit interactions in a qubit formed using the dopant dot so as to maximize a relaxation time of the qubit.

13. A method of fabricating a quantum processing system, the method comprising:
exposing a semiconductor substrate to atomic hydrogen H to form a monolayer of H and passivating the surface of the semiconductor substrate;
selectively desorbing H atoms from the passivated surface by the application of appropriate voltages and tunnelling currents to an STM tip, forming a plurality of patches in the H monolayer; wherein the orientation of the plurality of patches along a direction of the semiconductor lattice is selected to maximize relaxation time; and
incorporating a donor atom in each of the plurality of patches in the H monolayer, to form a donor molecule having a selected donor dot axis;
applying a magnetic field to the engineered quantum processing element, the direction of the magnetic field being perpendicular to the direction of the donor dot axis.

14. The method of fabricating of claim 13, further comprising:
desorbing the hydrogen monolayer;
overgrowing the surface with a layer of the semiconductor.

15. The method of fabricating of claim 13, wherein selectively desorbing H atoms further comprises desorbing H atoms to create one or more patches for creating one or more in-plane gates.

16. The method of fabricating of claim 13, further comprising:
depositing one or more gates above the positions of the donor atoms.

17. The method of fabricating of claim 16 further comprising: applying a voltage to the one or more gates to cause an electron to be confined in the donor molecule.

18. The method of claim 13, wherein the inter-donor axis is in a crystalline axis of the semiconductor substrate.

19. The method of claim 18, wherein the magnetic field is perpendicular to the direction.

20. The method of claim 13, wherein the inter-donor axis is in a crystalline axis of the semiconductor substrate.

21. The method of claim 20, wherein the magnetic field is perpendicular to the direction.

22. (canceled)
